(19) United States
(12) Patent Application Publication
(10) Pub. No.: US 2012/0261696 A1
(43) Pub. Date: Oct. 18, 2012

(54) LIGHT EMITTING DIODE EPITAXIAL STRUCTURE AND MANUFACTURING METHOD THEREOF

(75) Inventors: SHIH-CHENG HUANG, Hukou (TW); PO-MIN TU, Hukou (TW)

(73) Assignee: ADVANCED OPTOELECTRONIC TECHNOLOGY, INC., Hsinchu Hsien (TW)

(21) Appl. No.: 13/313,005

(22) Filed: Dec. 7, 2011

(30) Foreign Application Priority Data
Apr. 13, 2011 (CN) 201110091859.4

(51) Int. Cl. H01L 33/30; H01L 33/46

(52) U.S. Cl. 257/98; 438/29; 257/E33.068

(57) ABSTRACT

A light emitting device (LED) epitaxial structure includes a substrate, a nitride semiconductor layer, a patterned oxide total-reflective layer, a first-type semiconductor layer, an active layer and a second-type semiconductor layer. The nitride semiconductor layer is formed on the substrate. The patterned oxide total-reflective layer is formed on the nitride semiconductor layer. An upper surface of the nitride semiconductor layer is partially exposed out from the oxide total-reflective layer. The first-type semiconductor layer is arranged on the exposed upper surface of the nitride semiconductor layer and covers the oxide total-reflective layer. The active layer is arranged on the first-type semiconductor layer. The second-type semiconductor layer is arranged on the active layer.

### BACKGROUND

1. Technical Field

The present disclosure generally relates to solid state light emitting devices and, more particularly, to a light emitting diode (LED) epitaxial structure with high light extraction efficiency and manufacturing method thereof.

2. Discussion of Related Art

LEDs have many advantages, such as high luminosity, low operational voltage, low power consumption, compatibility with integrated circuits, easy driving, long term reliability, and environmental friendliness which have promoted the wide use of LEDs as a light source.

Generally, an LED epitaxial structure includes a substrate, an N-type semiconductor contact layer, an active layer and a P-type semiconductor contact layer arranged on the substrate in sequence. Part of light emitted from the active layer transmits to the substrate and is absorbed by the substrate; therefore, the light extraction efficiency of the LED epitaxial structure is decreased.

Therefore, what is needed is an LED epitaxial structure and manufacturing method thereof which can overcome the described limitations.

### BRIEF DESCRIPTION OF THE DRAWINGS

FIG. 1 is a cross-sectional view of an LED epitaxial structure, in accordance with a first embodiment of the present disclosure.

FIG. 2 is a cross-sectional view of an LED epitaxial structure, in accordance with a second embodiment of the present disclosure.

FIG. 3 is a diagram showing a relationship between an amount of layer of the oxide total-reflective layer and a reflective efficiency of the oxide total-reflective layer.

### DETAILED DESCRIPTION OF EMBODIMENTS

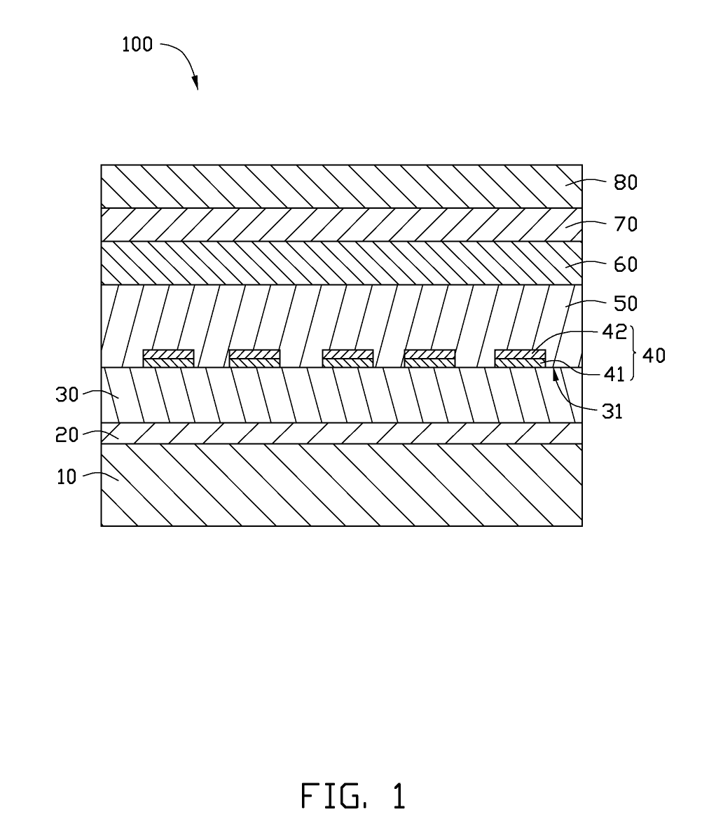

Referring to FIG. 1, an LED epitaxial structure 100, in accordance with a first embodiment, is provided. The LED epitaxial structure 100 includes a substrate 10, a buffer layer 20, a nitride semiconductor layer 30, an oxide total-reflective layer 40, an N-type layer 50, an active layer 60, a current block layer 70, and a P-type layer 80 arranged on the substrate 10 in sequence.

The substrate 10 preferably is a monocrystal plate and can be made of a material of sapphire, silicon carbide (SiC), silicon (Si), gallium arsenide (GaAs), lithium aluminate (LiAlO₂), magnesium oxide (MgO), zinc oxide (ZnO), GaN, aluminum nitride (AlN) or indium nitride (InN), etc. In the present embodiment, the substrate 10 is made of sapphire.

The buffer layer 20 is formed on an upper surface of the substrate 10. In the present embodiment, the buffer layer 20 is a nitride semiconductor layer.

The nitride semiconductor layer 30 is grown on the buffer layer 20 by epitaxy. The buffer layer 20 reduces the lattice mismatch between the substrate 10 and the grown nitride semiconductor layer 30. In the present embodiment, the nitride semiconductor layer 30 is a continuous layer with an upper surface 31 away from the buffer layer 20.

The oxide total-reflective layer 40 is formed on the upper surface 31 of the nitride semiconductor layer 30. The oxide total-reflective layer 40 is etched to form a plurality of independent patterns; therefore, the upper surface 31 of the nitride semiconductor layer 30 is partially exposed. In the present embodiment, each of the patterns of the oxide total-reflective layer 40 includes a SiO₂ layer 41 connected to the upper surface 31 of the nitride semiconductor layer 30 and a Ta₂O₅ layer 42 formed on the SiO₂ layer 41. A periodicity of the oxide total-reflective layer 40 is one. In the present embodiment, an upper surface of the Ta₂O₅ layer 42 of each pattern is planar, and all of the upper surfaces of the Ta₂O₅ layers 42 of the patterns are coplanar.

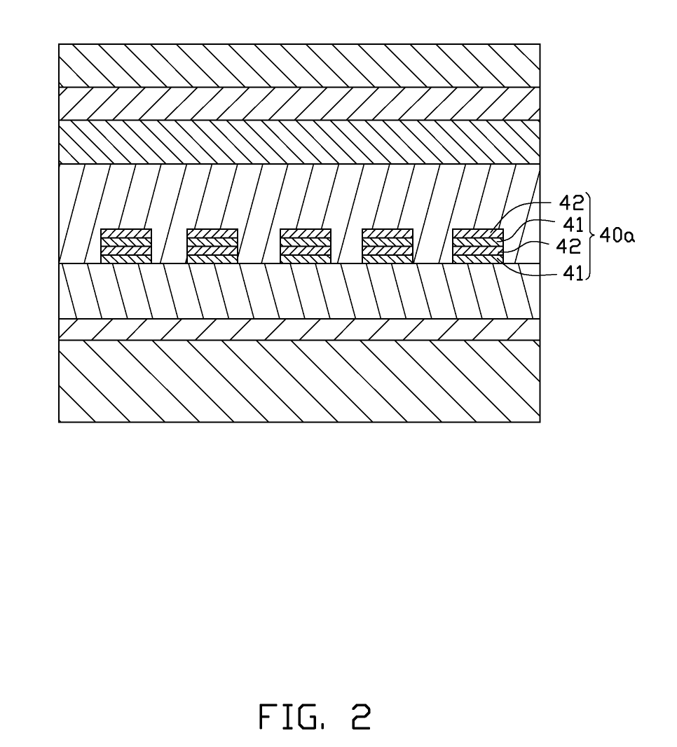

In alternative embodiments, the oxide total-reflective layer 40 can include two or more SiO₂ layers 41 and two or more Ta₂O₅ layers 42 alternated one by one. Referring to FIG. 2, an oxide total-reflective layer 40a that includes two SiO₂ layers 41 and two Ta₂O₅ layers 42 alternated one by one is shown. In other words, the periodicity of the oxide total-reflective layer 40a is two.

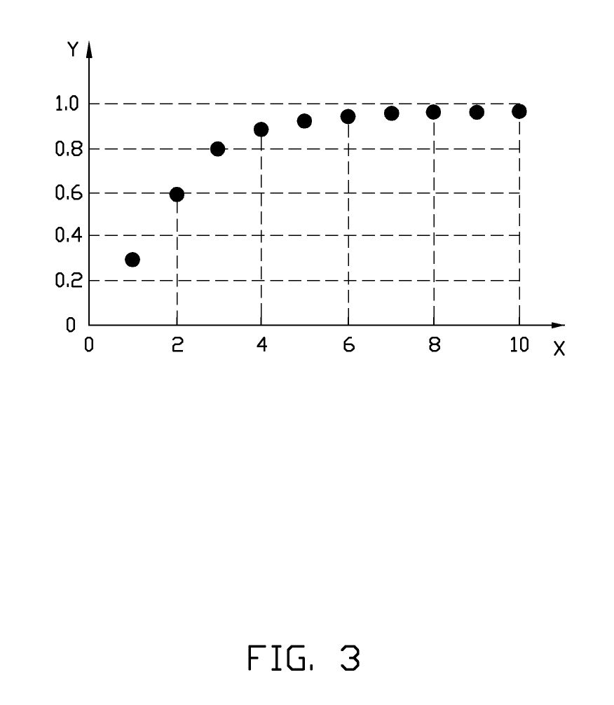

Referring to FIG. 3, a diagram showing a relationship between the periodicity of the oxide total-reflective layer and the reflective efficiency of the oxide total-reflective layer is provided. X-axis represents the periodicity of the oxide total-reflective layer, and Y-axis represents the reflective efficiency of the oxide total-reflective layer 40. It can be seen from the FIG. 3 that, the reflective efficiency of the oxide total-reflective layer 40 increases with the increasing of the periodicity of the oxide total-reflective layer. For example, when the periodicity of the oxide total-reflective layer is 2, i.e., the oxide total-reflective layer including two SiO₂ layers 41 and two Ta₂O₅ layers 42, the oxide total-reflective layer has a reflective efficiency about 60%. When the periodicity of the oxide total-reflective layer is 6, i.e., the oxide total-reflective layer including six SiO₂ layers 41 and six Ta₂O₅ layers 42, the oxide total-reflective layer has a reflective efficiency about 98%.

A thickness D₁ of the SiO₂ layer 41 satisfies condition:

D₁=λ/4×n₁,

wherein λ represents a wavelength of the LED epitaxial structure 100 and n₁ represents refraction index of the SiO₂ layer 41.

For example, when it is needed to manufacture a blue LED epitaxial structure with a wavelength of 450 nano meter, and the refraction index of the SiO₂ layer 41 is 1.47, the thickness D₁ of the SiO₂ layer 41 can be calculated as:

D₁=450/4×1.47=76.5 (nano meter).

A thickness D₂ of the Ta₂O₅ layer 42 satisfies condition:

D₂=λ/4×n₂,

wherein λ represents a wavelength of the LED epitaxial structure 100 and n₂ represents refraction index of the Ta₂O₅ layer 42.

For example, when it is needed to manufacture a blue LED epitaxial structure with a wavelength of 450 nano meter, and the refraction index of the Ta₂O₅ layer 42 is 2.2, the thickness D₂ of the Ta₂O₅ layer 42 can be calculated as:

D₂=450/4×2.2=51.1 (nano meter).

The N-type layer 50 is arranged on the exposed upper surface 31 of the nitride semiconductor layer 30 and covers the oxide total-reflective layer 40. The N-type layer 50 can be selected from n-type GaN, n-type InGaN, and n-type AlGaN.

The active layer 60 is arranged on an upper surface of the N-type layer 50, and can be selected from GaN, In_{y}Ga_{1-y}N, AlₓGa₁₋ₓN, and AlₓIn_{y}Ga_{1-x-y}N.

The current block layer 70 is arranged on an upper surface of the active layer 60. In the present embodiment, the current block layer 70 is a P-type current block layer.

The P-type layer 80 is arranged on an upper surface of the current block layer 70, and can be selected from p-type GaN, p-type InGaN, p-type AlGaN, and p-type AlInGaN.

The oxide total-reflective layer 40 can reflect light emitted from the active layer 60 to the outer surface of the LED epitaxial structure 100, therefore improving the light extraction efficiency of the LED epitaxial structure 100.

Referring to FIG. 1 again, a method for manufacturing an LED epitaxial structure in accordance with an exemplary embodiment is also disclosed, and includes:
step 1: providing a substrate 10;
step 2: forming a buffer layer 20 on the substrate 10;
step 3: forming a nitride semiconductor layer 30 on the buffer layer 20, the nitride semiconductor layer 30 having an upper surface 31 away from the buffer layer 20;
step 4: forming an oxide total-reflective layer 40 on the upper surface 31 of the nitride semiconductor layer 30;
step 5: patterning the oxide total-reflective layer 40 by etching, therefore partially exposing the upper surface 31 of the nitride semiconductor layer 30 uncovered by the oxide total-reflective layer 40;
step 6: forming an N-type layer 50 on the upper surface 31 of the nitride semiconductor layer 30 and covering the oxide total-reflective layer 40;
step 7: forming an active layer 60 on an upper surface of the N-type layer 50;
step 8: forming a current block layer 70 on an upper surface of the active layer; and
step 9: forming a P-type layer 80 on an upper surface of the current block layer.

In step 4, the oxide total-reflective layer 40 is formed including a SiO₂ layer 41 connected to the upper surface 31 of the nitride semiconductor layer 30 and a Ta₂O₅ layer 42 connected to the SiO₂ layer 41.

It is to be further understood that even though numerous characteristics and advantages have been set forth in the foregoing description of embodiments, together with details of the structures and functions of the embodiments, the disclosure is illustrative only; and that changes may be made in detail, especially in matters of shape, size, and arrangement of parts within the principles of the disclosure to the full extent indicated by the broad general meaning of the terms in which the appended claims are expressed.

What is claimed is:

1. A light emitting device (LED) epitaxial structure comprising:
a substrate;
a nitride semiconductor layer formed on the substrate;
a patterned oxide total-reflective layer formed on an upper surface of the nitride semiconductor layer, the upper surface of the nitride semiconductor layer being partially exposed out from the oxide total-reflective layer;
a first-type semiconductor layer covering the exposed upper surface of the nitride semiconductor layer and the oxide total-reflective layer;
an active layer arranged on the first-type semiconductor layer; and
a second-type semiconductor layer arranged on the active layer.

2. The LED epitaxial structure of claim 1, wherein the oxide total-reflective layer comprises a SiO₂ layer connected to the upper surface of the nitride semiconductor layer and a Ta₂O₅ layer connected to the SiO₂ layer.

3. The LED epitaxial structure of claim 2, wherein a thickness D₁ of the SiO₂ layer, a wavelength λ of the LED epitaxial structure, and a refraction index of the SiO₂ layer satisfy the following condition:
D₁=λ/4×n₁.

4. The LED epitaxial structure of claim 2, wherein a thickness D₂ of the Ta₂O₅, a wavelength λ of the LED epitaxial structure, and a refraction index of the Ta₂O₅ layer satisfy condition:
D₂=λ/4×n₂.

5. The LED epitaxial structure of claim 1, wherein the oxide total-reflective layer comprises a plurality of SiO₂ layers and a plurality of SiO₂ layers alternated one by one.

6. A method for manufacturing an LED device comprising:
providing a substrate;
forming a nitride semiconductor layer on the substrate, the nitride semiconductor layer having an upper surface away from the buffer layer;
forming an oxide total-reflective layer on the upper surface of the nitride semiconductor layer;
patterning the oxide total-reflective layer by etching, thereby partially exposing the upper surface of the nitride semiconductor layer uncovered by the oxide total-reflective layer;
forming an N-type layer on the upper surface of the nitride semiconductor layer, wherein the N-type layers covers the oxide total-reflective layer;
forming an active layer on an upper surface of the N-type layer; and
forming a P-type layer on an upper surface of the current block layer.

7. The method of claim 6, wherein the oxide total-reflective layer comprising a SiO₂ layer connected to the upper surface of the nitride semiconductor layer and a Ta₂O₅ layer connected to the SiO₂ layer.

8. The method of claim 6, wherein a thickness D₁ of the SiO₂ layer, a wavelength λ of the LED epitaxial structure, and a refraction index of the SiO₂ layer satisfy the following condition:
D₁=λ/4×n₁.

9. The method of claim 8, wherein a thickness D₂ of the Ta₂O₅ layer, a wavelength λ of the LED epitaxial structure, and a refraction index n₂ of the Ta₂O₅ layer satisfy condition:
D₂=λ/4×n₂.
